(19) United States
(12) Patent Application Publication
(10) Pub. No.: US 2005/0142872 A1
(43) Pub. Date: Jun. 30, 2005

(54) Method of forming fine pattern for semiconductor device

(75) Inventor: Se Jin Park, Yeoju-kun (KR)

Correspondence Address: THE LAW OFFICES OF ANDREW D. FORTNEY, PH.D., P.C., 7257 N. MAPLE AVENUE, BLDG. D, 3107, FRESNO, CA, 93720, US

(73) Assignee: DongbuAnam Semiconductor Inc.

(21) Appl. No.: 11/026,572

(22) Filed: Dec. 30, 2004

(30) Foreign Application Priority Data
Dec. 30, 2003 (KR) 10-2003-0100536

(51) Int. Cl. H01L 21/44

(52) U.S. Cl. 438/675

(57) ABSTRACT

An object of the present invention is to provide a method that is capable of forming easily a fine pattern corresponding to a high integration density device, without using a new exposure apparatus. The object of the present invention as noted above is accomplished by etching a second insulating layer to expose a portion of an underlying first insulating layer; forming a third insulating layer on the entire surface of the substrate; etching the third insulating layer and the first insulating layer using the second insulating layer as an etch barrier, to define a pattern region; forming a material layer on the entire surface of the substrate so as to fill the pattern region; and planarizing the material layer and/or substrate so as to expose the first insulating layer, to form a pattern.

### BACKGROUND OF THE INVENTION

(a) Field of the Invention

The present invention relates to a method of manufacturing a semiconductor device, and more particularly to a method of forming a fine pattern for a semiconductor device.

(b) Description of the Related Art

In fabricating a semiconductor device, a conductive layer pattern or an insulating layer pattern is generally formed by a deposition process, a photolithography process and an etching process. The photolithography process generally includes coating a photoresist layer, exposing the photoresist layer and developing the exposed photoresist layer, to form a photoresist pattern. The critical dimension (CD) of this photoresist pattern has effect on the CD of the conductive layer pattern or the insulating layer pattern.

Accordingly, for the purpose of obtaining the CD of a fine pattern corresponding to a high integration density device, a light source of a short wavelength such as KrF (λ=248 nm) or ArF (λ=193 nm) instead of I-line (λ=365 nm) light source must be employed in an exposure apparatus. However, in case of using the light source of the short wavelength, there is a problem in that fabrication cost is very expensive owing to employing a new exposure apparatus and a new photoresist.

To overcome this problem, a double exposure method exposing a photoresist layer by double exposure while applying a conventional exposure apparatus employing an I-line (λ=365 nm) or a G-line (λ=436 nm) light source to form a fine photoresist pattern has been used. However, this method has problems in that it is difficult to obtain the minimum line width of the photoresist pattern due to wave motion of the exposure beam and collapse of the photoresist pattern occurs.

### SUMMARY OF THE INVENTION

An object of the present invention is to provide a method that is capable of easily forming a fine pattern corresponding to a high integration and/or high density device, without using a new exposure apparatus.

The object of the present invention as noted above is accomplished by a method of forming a pattern for a semiconductor device, that includes: etching a second insulating layer to expose a portion of an underlying first insulating layer on a semiconductor substrate; forming a third insulating layer on the entire surface of the substrate; etching the third insulating layer and the first insulating layer using the second insulating layer as an etch barrier, to define a pattern region; forming a layer of material on the entire surface of the substrate so as to fill the pattern region; and planarizing so as to expose the first insulating layer.

Furthermore, the first insulating layer and the third insulating layer respectively have a high etching selectivity to the second insulating layer. Preferably, the first insulating layer and the third insulating layer comprise an oxide layer, and the second insulating layer comprises a nitride layer.

### BRIEF DESCRIPTION OF THE DRAWINGS

A further understanding of nature and advantage of the present invention will become apparent by reference to the remaining portions of the specification and drawings, in which:

FIGS. 1A-1F are cross-sectional views describing a method of forming a fine pattern for a semiconductor device according to an embodiment of the present invention.

### DETAILED DESCRIPTION OF THE PREFERRED EMBODIMENTS

The present invention will now be described more fully hereinafter with reference to the accompanying drawings, in which a preferred embodiment of the invention is shown. The present invention may, however, be embodied in many different forms, and should not be construed as being limited to the embodiment set forth herein.

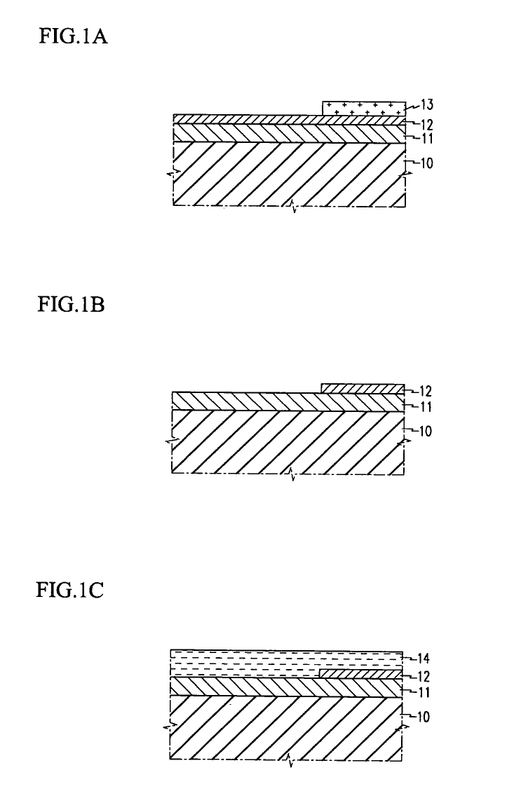

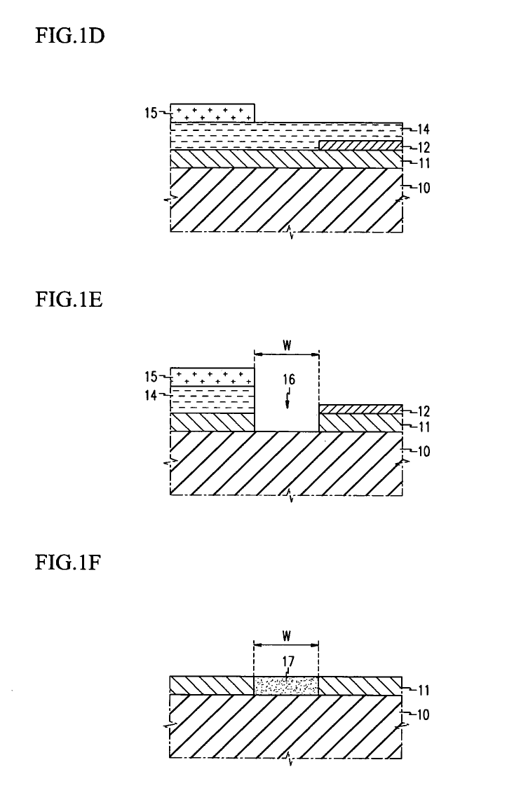

A method of forming a fine pattern for a semiconductor device according to an embodiment of the present invention will be described with reference to FIGS. 1A-1F.

As shown in FIG. 1A, a first insulating layer 11 is formed on a semiconductor substrate 10, and a second insulating layer 12 having high etching selectivity to the first insulating layer 11 is then formed on the first insulating layer 11. Preferably, the first insulting layer 11 is formed of an oxide layer such as a silicon oxide (SiO₂) and the second insulating layer 12 is formed of a nitride layer such as a silicon nitride (SiN). More preferably, the oxide layer is formed by thermal oxidation process and the nitride layer is formed by Chemical Vapor Deposition (CVD), Low Pressure (LP)-CVD or Plasma Enhanced (PE)-CVD.

Thereafter, a first photoresist layer is coated on the second insulating layer 12, is exposed by a conventional exposure apparatus employing an I-line light source, and is developed, to form a first photoresist pattern 13 exposing the portion of the second insulating layer 12. Here, an anti-reflective coating (ARC or ARC layer) may be formed under the first photoresist pattern 13 (not shown in FIG. 1A).

As shown in FIG. 1B, the exposed portion of the second insulating layer 12 is etched by an etching process using the first photoresist pattern 13 as an etch mask and the first insulating layer 11 as an etch barrier, to expose the portion of the first insulating layer 11. The first photoresist 13 is then removed by a well-known method.

As shown in FIG. 1C, a third insulating layer 14 having high etching selectivity to the second insulating layer 12 is formed on the entire surface of the substrate. Preferably, the third insulating layer 14 is formed of an oxide layer such as silicon oxide (SiO₂), the same as the first insulating layer 11. At least a portion of the third insulating layer 14 has a lower surface that is substantially coplanar with a lower surface of the second insulating layer 12.

As shown in FIG. 1D, a second photoresist layer is coated on the third insulating layer 14, is exposed by a conventional exposure apparatus employing an I-line light source, and is developed, to form a second photoresist pattern 15 exposing the portion of the third insulating layer 14. Here, an Anti-Reflective Coating (ARC) layer may be formed under the first photoresist pattern 15 (not shown in FIG. 1D).

As shown in FIG. 1E, the third insulating layer 14 and the first insulating layer 11 are etched by an etching process using the second photoresist pattern 15 as an etch mask and the second insulating layer as an etch barrier so as to expose the portion of the substrate 10. Generally, all of the portion(s) of the third insulating layer 14 that overlie the second insulating layer 12 are removed, leaving only portion(s) of the third insulating layer 14 that are substantially coplanar with the second insulating layer 12. As a result, a pattern region 16 having a fine width W is defined. The fine width W is smaller than a minimum width that can be formed by the conventional exposure apparatus employing an I-line light source.

As shown in FIG. 1F, the second photoresist pattern 15 is removed by a well-known method. A copper (Cu) layer as a material layer for use as a metallization structure is then deposited on the entire surface of the substrate so as to fill the pattern region 16. Thereafter, a planarization process is performed by Chemical Mechanical Polishing (CMP) so as to expose the first insulating layer 11, thereby forming a copper pattern 17 having the fine width W. For example, a single, non-selective CMP process can planarize the fill material and both of the second and third insulating layers 12 and 14, in which case disappearance of the second insulating layer 12 can serve as an endpoint. Alternatively, planarizing may comprise multiple steps; for example, the fill material may be removed from regions or areas outside the pattern region 16 by CMP, second and third insulating layers 12 and 14 may be removed by selective etching (in which case third insulating layer 14 comprises a material different from first insulating layer 11), and the fill material may be made substantially coplanar with first insulating layer 11 by a second CMP step.

In the present invention as described above, the copper pattern having the fine width is formed by the conventional exposure apparatus using the I-line light source. As a result, the present invention can easily fabricate a high integration density device. Furthermore, the present invention can lower fabrication cost as there is no need to use a new exposure apparatus. Furthermore, the present invention can prevent collapse of a photoresist pattern as there is no need to use a double exposure method, to improve yield and reliability of a device.

While the present invention has been described in detail with reference to the preferred embodiments, it is to be understood that the invention is not limited to be disclosed embodiments, but, on the contrary, is intended to cover various modifications and equivalent arrangements included within the spirit and scope of the appended claims.

1. A method of forming a pattern for a semiconductor device, comprising the steps of:
etching a second insulating layer to expose a portion of an underlying first insulating layer on a semiconductor substrate;
forming a third insulating layer on the entire surface of the substrate;
etching the third insulating layer and the first insulating layer using the second insulating layer as an etch barrier, to define a pattern region;
forming a layer of material on the entire surface of the substrate so as to fill the pattern region; and
planarizing the layer of material so as to expose the first insulating layer.

2. The method of claim 1, wherein the first insulating layer and the third insulating layer respectively have high etching selectivity to the second insulating layer.

3. The method of claim 2, wherein each of the first insulating layer and the third insulating layer comprise an oxide layer.

4. The method of claim 2, wherein the second insulating layer comprises a nitride layer.

5. The method of claim 1, wherein etching the second insulating layer comprises forming a photoresist pattern with an exposure apparatus having an I-line light source, and using the photoresist pattern as an etch mask.

6. The method of claim 1, wherein etching the third insulating layer and the first insulating layer comprises forming a photoresist pattern with an exposure apparatus having an I-line light source, and using the photoresist pattern as an etch mask.

7. The method of claim 1, wherein the pattern region has a width smaller than a minimum width that can be formed by an exposure apparatus having an I-line light source.

8. The method of claim 1, wherein the layer of material comprises a copper layer.

9. The method of claim 1, wherein planarizing comprises Chemical Mechanical Polishing (CMP).

10. The method of claim 1, further comprising sequentially forming the first insulating layer and the second insulating layer on the semiconductor substrate.
